(19) United States
(12) Patent Application Publication
(10) Pub. No.: US 2025/0388083 A1
(43) Pub. Date: Dec. 25, 2025

(54) DISPLAY DEVICE AND VEHICLE

(71) Applicant: BOE Technology Group Co., Ltd., Beijing (CN)

(72) Inventors: Lijuan ZHAO, Beijing (CN); Hong ZHU, Beijing (CN); Sitong CHEN, Beijing (CN)

(21) Appl. No.: 18/881,264

(22) PCT Filed: Mar. 13, 2024
(86) PCT No.: PCT/CN2024/081424

§ 371 Date: Jan. 4, 2025

(30) Foreign Application Priority Data
Apr. 28, 2023 (CN) 202310483605.X

(51) Int. Cl. B60K 35/22; B60K 35/53

(52) U.S. Cl. CPC B60K 35/223; B60K 35/53; B60K 2360/816

(57) ABSTRACT

A display device includes a first housing, a second housing, a roller, a pulley assembly, a stressed member, and a flexible display panel. The first housing includes a fixed portion and a sliding portion slidably connected to the fixed portion. The second housing is fixedly connected to a side of the fixed portion away from the sliding portion, and an angle between the first housing and the second housing is less than 180 degrees. The roller is disposed between the first housing and the second housing, and the roller is rotatably connected to at least one of the first housing and the second housing. The pulley assembly comprises a pulley block in the first housing, and a tension belt wound around the pulley block, and the pulley block is respectively connected to the fixed portion and the sliding portion.

The present application is a US national stage of international application No. PCT/CN2024/081424, filed on Mar. 13, 2024, which claims priority to Chinese Patent Application No. 202310483605.X, filed on Apr. 28, 2023 and entitled “DISPLAY DEVICE AND VEHICLE”, the entire content of which is incorporated herein by reference.

### TECHNICAL FIELD

The present application relates to the field of display technology, and in particular to a display device and a vehicle.

### BACKGROUND

Currently, a display device can use a flexible display panel as a display screen. Compared with a traditional display panel, the flexible display panel has advantages of being deformable, bendable and more flexible and so on.

The display device generally includes a flexible display panel and a support assembly, and a part of the flexible display panel is fixed on the support assembly. The support assembly can drive the flexible display panel to be unfolded or rolled up after being subjected to an external force to enable the display device to have an unfolded state and a contracted state, thereby realizing the function of adjusting the size of the display surface of the display device.

However, the weight of the support assembly in the display device is large, resulting in the need to apply a large driving force to the support member for driving.

### SUMMARY

An embodiment of the present application provides a display device, which can solve the problem that the display device in the prior art is difficult to drive due to the fact that a large driving force is required. A technical solution described is as follows.

In one aspect, a display device is provided, and the display device includes:
a first housing, where the first housing includes a fixed portion and a sliding portion slidably connected to the fixed portion;
a second housing, where the second housing is fixedly connected to a side of the fixed portion away from the sliding portion, and an angle between the first housing and the second housing is less than 180 degrees;
a roller, where the roller is disposed between the first housing and the second housing, and the roller is rotatably connected to at least one of the first housing and the second housing;
a pulley assembly, where the pulley assembly includes a pulley block in the first housing, and a tension belt wound around the pulley block, and the pulley block is respectively connected to the fixed portion and the sliding portion;
a stressed member, where the stressed member is disposed in the second housing and is fixedly connected to an end portion of the tension belt away from the pulley block; and
a flexible display panel, where the flexible display panel includes a curled display portion wound on the roller and a first planar display portion and a second planar display portion disposed at two sides of the curled display portion, the first planar display portion is connected to the sliding portion in the first housing, and the second planar display portion is connected to the stressed member in the second housing.

Optionally, the pulley block includes at least one fixed pulley and at least one movable pulley, a bracket in the at least one movable pulley is fixedly connected to the sliding portion, a bracket in the at least one fixed pulley is fixedly connected to the fixed portion, and the at least one movable pulley is closer to the roller than the at least one fixed pulley; and
an end portion of the tension belt away from the stressed member is connected to a bracket in the movable pulley or a bracket in the fixed pulley, and the tension belt is wound around a pulley in the at least one movable pulley and a pulley in the at least one fixed pulley.

Optionally, in a case that the pulley block includes one fixed pulley and one movable pulley, the end portion of the tension belt away from the stressed member is connected to the bracket in the fixed pulley, and the tension belt is successively wound around a pulley in the movable pulley and a pulley in the fixed pulley and is then connected to the stressed member.

Optionally, in a case that the pulley block includes two fixed pulleys and one movable pulley, the two fixed pulleys are a first fixed pulley and a second fixed pulley, and the first fixed pulley is closer to the roller than the second fixed pulley; the end portion of the tension belt away from the stressed member is connected to a bracket in the movable pulley, and the tension belt is successively wound around a pulley of the first fixed pulley, a pulley of the movable pulley and a pulley of the second fixed pulley and is then connected to the stressed member.

Optionally, in a case that the pulley block includes two fixed pulleys and two movable pulleys, the two fixed pulleys are a first fixed pulley and a second fixed pulley, and the first fixed pulley is closer to the roller than the second fixed pulley; the two movable pulleys are a first movable pulley and a second movable pulley, and the first movable pulley is closer to the roller than the second movable pulley; the end portion of the tension belt away from the stressed member is connected to a bracket in the first fixed pulley, and the tension belt is successively wound around a pulley of the second movable pulley, a pulley of the first fixed pulley, a pulley of the first movable pulley and a pulley of the second fixed pulley and is then connected to the stressed member.

Optionally, an arrangement direction of the at least one movable pulley and the at least one fixed pulley is parallel to a sliding direction of the sliding portion relative to the fixed portion.

Optionally, the display device also includes a first steering shaft and a second steering shaft, the first steering shaft is fixed at a position where the fixed portion and the second housing are connected, and the second steering shaft is disposed at a side of the stressed member away from the roller in the second housing and is connected to the second housing; and a central axis of the first steering shaft and a central axis of the second steering shaft are both parallel to a central axis of the roller; and
the end portion of the tension belt away from the pulley block is successively wound around the first steering shaft and the second steering shaft and is then connected to the stressed member.

Optionally, the tension belt includes a first sub-tension belt and a second sub-tension belt, a first end of the first sub-tension belt is connected to the pulley block, and a first end of the second sub-tension belt is connected to the stressed member; the display device further includes a buffer assembly arranged between the first steering shaft and the second steering shaft, and two ends of the buffer assembly are respectively connected to a second end of the first sub-tension belt and a second end of the second sub-tension belt.

Optionally, the buffer assembly includes a first connecting member and a second connecting member which are clamped to each other and an elastic element disposed between the first connecting member and the second connecting member, two ends of the elastic element are respectively connected to the first connecting member and second connecting member; an end of the first connecting member away from the elastic element is connected to the second end of the first sub-tension belt, and an end of the second connecting member away from the elastic element is connected to the second end of the second sub-tension belt.

Optionally, one of the first connecting member and the second connecting member is provided with a clamping protrusion and the other of the first connecting member and the second connecting member is provided with a clamping groove matched with the clamping protrusion; and in a case that the clamping protrusion is clamped to the clamping groove, the first connection member and the second connection member are clamped.

Optionally, a pulley in the pulley block, the first steering shaft and the second steering shaft are all provided with external teeth, and the tension belt is provided with internal teeth that engage with the external teeth.

Optionally, the display device further includes a driving component fixed in the second housing and connected to the stressed member, and the driving component is configured to drive the stressed member to move along a direction perpendicular to the roller.

Optionally, the driving assembly includes a driving motor, a transmission shaft and a transmission member, and the driving motor is fixed in the second housing and is connected to one end of the transmission shaft; the transmission member is sleeved on the transmission shaft and is connected to the stressed member; and the transmission shaft is arranged perpendicular to the roller; and
the driving motor is configured to drive the transmission shaft to rotate such that the transmission member drives the stressed member to move along a length direction of the transmission shaft.

Optionally, the display device further includes a coil spring disposed between the second planar display portion and the stressed member, the coil spring includes a winding core and a fixed member fixed to one end of the winding core, the other end of the winding core is connected to the second planar display portion, and the fixed member is fixed to the stressed member.

In another aspect, there is provided a vehicle including:
a display device fixed in a cabin of the vehicle, and the display device may be the display device given in any of the above.

Technical solutions provided by embodiments of the present application bring the following beneficial effects.

A display device may include a first housing, a second housing, a roller, a pulley assembly, a stressed member and a flexible display panel. Through the cooperation of the flexible display panel with the pulley block, the tension belt, the roller and the two housings, when the stressed member moves along an X1 axis direction under an external force, the stressed member can drive the end of the tension belt away from the pulley block to move along a direction close to the roller; and the tension belt wound around the pulley block can apply a force to the sliding portion in the first housing in a direction away from the roller through the pulley block, so that the sliding portion can move relative to the fixed portion, and thus the first planar display portion can drive the entire flexible display panel to be unfolded. In this way, the cooperation of the tension belt and the pulley block can effectively reduce the pushing force which is required when the flexible display panel is unfolded (the pushing force is applied to the stressed member and is finally transferred to the sliding portion connected to the first planar display portion), thereby improving the operation convenience and use experience of the display device. In addition, when the stressed member moves along an X2 axis direction under an external force, the stressed member can apply a force to the second planar display portion in the flexible display panel to drive the entire flexible display panel to descend, so that the flexible display panel can contract.

### BRIEF DESCRIPTION OF DRAWINGS

In order to more clearly illustrate the technical solutions in the embodiments of the present application, the accompanying drawings to be used in the description of the embodiments will be briefly introduced below, and it will be obvious that the accompanying drawings in the following description are only some of the embodiments of the present application, and other accompanying drawings can be obtained according to these drawings for the people of ordinary skill in the field without putting forth any creative labor.

FIG. 1 is a schematic view of an outer structure of a display device provided by an embodiment of the present application;

FIG. 2 is a sectional view of the display device shown in FIG. 1;

FIG. 3 is a partially exploded schematic view of the display device shown in FIG. 1;

FIG. 4 is a sectional view of another display device provided by an embodiment of the present application;

FIG. 5 is a schematic diagram of a structure of a driving assembly provided by an embodiment of the present application;

FIG. 6 is a sectional view of another display device provided by an embodiment of the present application;

FIG. 7 is a schematic view of an effect of switching between unfolding and contracting a flexible display panel in a display device provided by an embodiment of the present application;

FIG. 8 is a sectional view of yet another display device provided by an embodiment of the present application;

FIG. 9 is a schematic view of an effect of switching between unfolding and contracting the flexible display panel in the display device shown in FIG. 8;

FIG. 10 is a sectional view of a display device provided by another embodiment of the present application;

FIG. 11 is a schematic view of an effect of switching between unfolding and contracting the flexible display panel in the display device shown in FIG. 10;

FIG. 12 is a sectional view of a display device provided by another embodiment of the present application;

FIG. 13 is a schematic diagram of connection among a tension belt, a pulley and a steering shaft provided by an embodiment of the present application;

FIG. 14 is a sectional view of another display device provided by another embodiment of the present application;

FIG. 15 is a block diagram of a vehicle provided by an embodiment of the present application; and

FIG. 16 is a schematic view of an effect of switching between unfolding and contracting the display device in a vehicle provided by an embodiment of the present application.

Definite embodiments of the present application have been shown by means of the above-described accompanying drawings, which will be described in greater detail later. These accompanying drawings and textual descriptions are not intended to limit the scope of the present application idea in any way, but rather to illustrate the concepts of the present application for those skilled in the art by reference to particular embodiments.

### DETAILED DESCRIPTION

In order to make the purpose, technical solutions and advantages of the present application clearer, embodiments of the present application will be further described in detail below with reference to the accompanying drawings.

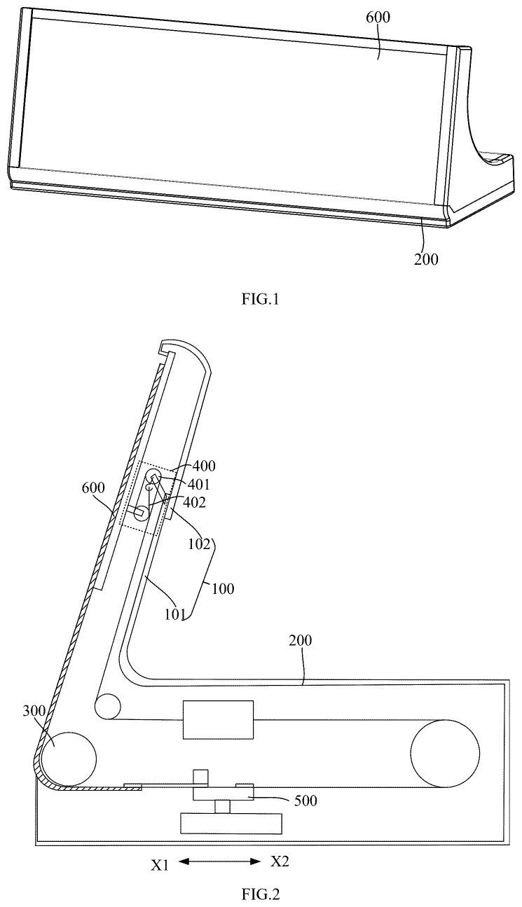

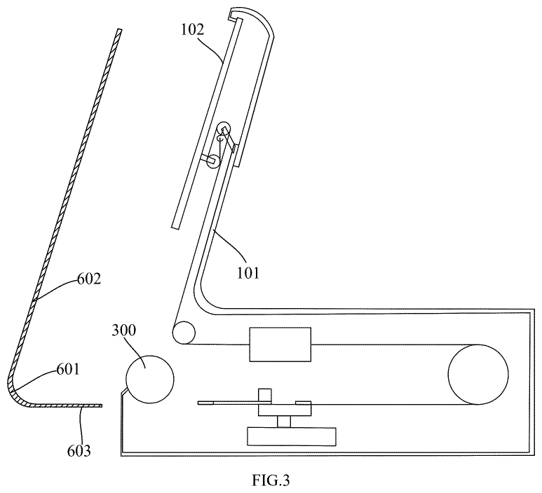

Please refer to FIGS. 1, 2 and 3. FIG. 1 is a schematic view of an outer structure of a display device provided by an embodiment of the present application, FIG. 2 is a sectional view of the display device shown in FIG. 1, and FIG. 3 is a partially exploded schematic view of the display device shown in FIG. 1. The display device may include a first housing 100, a second housing 200, a roller 300, a pulley assembly 400, a stressed member 500 and a flexible display panel 600.

The first housing 100 in the display device may include a fixed portion 101 and a sliding portion 102 slidably connected to the fixed portion 101.

The second housing 200 in the display device may be fixedly connected to a side of the fixed portion 101 away from the sliding portion 102, and an angle between the first housing 100 and the second housing 200 is less than 180 degrees.

The roller 300 in the display device may be located between the first housing 100 and the second housing 200, and the roller 300 may be rotatably connected to at least one of the first housing 100 and the second housing 200.

The pulley assembly 400 in the display device may include a pulley block 401 in the first housing 100, and a tension belt 402 wound around the pulley block 401. The pulley block 401 in the pulley assembly 400 may be connected to the fixed portion 101 and the sliding portion 102 in the first housing 100, respectively.

The stressed member 500 in the display device may be arranged in the second housing 200, and the stressed member 500 may be fixedly connected to an end portion of the tension belt 402 away from the pulley block 401.

The flexible display panel 600 in the display device may include a curled display portion 601 wound on the roller 300, and a first planar display portion 602 and a second planar display portion 603 located at two sides of the curled display portion 601. The first planar display portion 602 in the flexible display panel 600 is connected to the sliding portion 102 in the first housing 100, and the second planar display portion 603 is connected to the stressed member 500 in the second housing 200. It should be noted that the angle between the first housing 100 and the second housing 200 may be an angle between the first planar display portion 602 and the second planar display portion 603 in the flexible display panel 600.

In the embodiment of the present application, through the cooperation of the flexible display panel 600 with the pulley block 401, the tension belt 402, the roller 300 and the two housings, when the stressed member 500 moves along an X1 axis direction under an external force, the stressed member 500 can drive the end portion of the tension belt 402 away from the pulley block 401 to move along a direction close to the roller 300; and the tension belt 402 wound around the pulley block 401 can apply a force to the sliding portion 102 in the first housing 100 in a direction away from the roller 300 through the pulley block 401, so that the sliding portion 102 can move relative to the fixed portion 101, and thus the first planar display portion 602 can drive the entire flexible display panel 600 to be unfolded. In this way, the cooperation of the tension belt 402 and the pulley block 401 can effectively reduce the pushing force which is required when the flexible display panel 600 is unfolded (the pushing force is applied to the stressed member and is finally transferred to the sliding portion connected to the first planar display portion), thereby improving the operation convenience and use experience of the display device. In addition, when the stressed member 500 moves along an X2 axis direction under an external force, the stressed member 500 can apply a force to the second planar display portion 603 in the flexible display panel 600 to drive the entire flexible display panel 600 to descend, so that the flexible display panel can contract.

It should be noted that, in the process of unfolding the flexible display panel 600 in the display device, it usually needs to overcome gravity of the sliding portion 102 connected to the flexible display panel 600. In the present application, when the pulley block 401 and the tension belt 402 configured to lift the sliding portion 102 are arranged in the display device, a driving force for driving the sliding portion 102 to ascend can be effectively saved, so that the operation is more convenient.

For example, the flexible display panel 600 in the display device can flexibly adjust the size of the display surface of the flexible display panel in the process of unfolding and contracting, so that the flexible displaying panel 600 is suitable for different use scenarios. For example, when the display device is used on a vehicle (for example a car), the size of the flexible display panel extending from the display device can be flexibly adjusted, so that the flexible display panel is suitable for different use scenarios of the vehicle. In this way, it is possible to satisfy the user's requirements for entertainment and safety, and the requirement for the installation space of the vehicle is low. Especially for the large-size flexible display screen, the size of the flexible display screen can be adjusted according to different use scenarios in the vehicle environment. For example, when the vehicle is running, part of the flexible display screen is accommodated in the internal space of the display device, so that the display area of the flexible display screen is reduced, and the running information of the vehicle is provided by using a smaller display screen, thereby providing a good driving view. When the vehicle is in an entertainment state, a large part or all of the flexible display screen extends out of the internal space of the display device, so that the display area is increased, and the entertainment requirement of users is met.

In summary, embodiments of the present application provide a display device that may include: a first housing, a second housing, a roller, a pulley assembly, a stressed member and a flexible display panel. Through the cooperation of the flexible display panel with the pulley block, the tension belt, the roller and the two housings, when the stressed member moves along an X1 axis direction under an external force, the stressed member can drive the end of the tension belt away from the pulley block to move along a direction close to the roller; and the tension belt wound around the pulley block can apply a force to the sliding portion in the first housing in a direction away from the roller through the pulley block, so that the sliding portion can move relative to the fixed portion, and thus the first planar display portion can drive the entire flexible display panel to be unfolded. In this way, the cooperation of the tension belt and the pulley block can effectively reduce the pushing force which is required when the flexible display panel is unfolded (the pushing force is applied to the stressed member and is finally transferred to the sliding portion connected to the first planar display portion), thereby improving the operation convenience and use experience of the display device. In addition, when the stressed member moves along an X2 axis direction under an external force, the stressed member can apply a force to the second planar display portion in the flexible display panel to drive the entire flexible display panel to descend, so that the flexible display panel can contract.

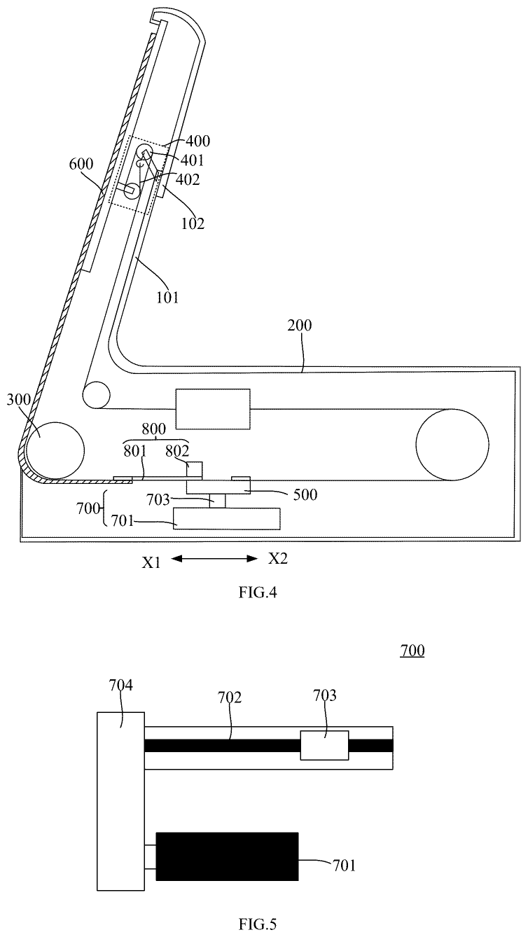

In an embodiment of the present application, please refer to FIG. 4 which is a sectional view of another display device provided by an embodiment of the present application. The display device may further include a driving assembly 700. The driving assembly 700 may be fixed in the second housing 200, and the driving assembly 700 may be connected to the stressed member 500. The driving assembly 700 may be configured to drive the stressed member 500 move in a direction perpendicular to the roller 300. In this case, by arranging the driving assembly 700 in the display device, the stressed member 500 can be driven to move by the driving assembly 700, so as to drive the flexible display panel 600 in the display device to unfold and contract, thereby improving the automation degree of the display device. In the present application, the display device further includes a control assembly (not shown in the figure) electrically connected to the driving assembly 700, and the control assembly can control the driving assembly to work normally after receiving the driving instruction. In the present application, the driving assembly 700 may be disposed in the second housing 200, without having to be disposed on a back of a movable plate connected to the flexible display panel in the related art, which increases the space utilization in the second housing.

Optionally, please refer to FIGS. 4 and 5. FIG. 5 is a schematic diagram of a structure of a driving assembly provided by an embodiment of the present application. The driving assembly 700 may include a driving motor 701, a transmission shaft 702 and a transmission member 703. The driving motor 701 may be fixed in the second housing 200, and the driving motor 701 may be connected to one end of the transmission shaft 702, the transmission member 703 may be sleeved on the transmission shaft 702, and the transmission member 703 may be connected to the stressed member 500. The transmission shaft 702 may be arranged perpendicular to the roller 300. The driving motor 701 may be configured to drive the transmission shaft 702 to rotate, so that the transmission member 703 drives the stressed member 500 to move along a length direction of the transmission shaft 702. In this case, when the driving motor 701 works, the driving motor 701 can drive the transmission shaft 702 to rotate, and the transmission shaft 702 can drive the transmission member 703 to move on the transmission shaft 702 during the rotation of the transmission shaft. Further, the transmission member 703 may drive the stressed member 500 to move along the length direction of the transmission shaft 702. After the flexible display panel 600 in the display device moves to a designated position, the control assembly controls the driving motor 701 to stop working, and the stressed member 500 stops moving. In addition, when a driving force is applied to the stressed member 500 by the driving motor 701, the driving motor 701 with smaller power can be selected to complete a smooth switching between an unfolding state and a contracting state of the flexible display panel 600 in the display device by a labor-saving effect brought by the pulley block 401 and the tension belt 402 in the display device. The volume of the driving motor 701 used can be reduced, so that the overall volume of the display device integrated with the driving motor 701 is smaller, which is convenient for a miniaturized design of the display device.

In the present application, as shown in FIG. 5, the driving assembly 700 may further include an adapter 704, which may be respectively connected to an output shaft of the driving motor 701 and an end of the transmission shaft 702, and the driving motor 701 and the transmission shaft 702 may be arranged in parallel. In this way, the arrangement of the components in the display device can be made more compact. For example, the transmission shaft 702 in the driving assembly 700 may be a lead screw, and the transmission member 703 may be a sliding block (e.g., a nut) sleeved on the lead screw. In the present application, the stressed member 500 may be a stressed plate, and the transmission member 703 is connected to one side of the stressed plate close to the driving motor 701.

In the embodiment of the present application, as shown in FIG. 2 and FIG. 4, the display device may further include a coil spring 800 located between the second planar display portion 603 and the stressed member 500 in the flexible display panel 600. The coil spring 800 may include a winding core 801 and a fixing member 802 fixedly connected to one end of the winding core 801, the other end of the winding core 801 may be connected to the second planar display portion 603, and the fixing member 802 may be fixed to the stressed member 500. In this case, the coil spring 800 is disposed between the second planar display portion 603 and the stressed member 500 in the flexible display panel 600, the fixing member 802 in the coil spring 800 is fixed on the stressed member 500, and one end of the winding core 801 in the coil spring 800 is connected to the second planar display portion 603. Thus, when the flexible display panel 600 in the display device is switched between the unfolding state and the contracting state, the coil spring 800 can compensate for the movement of the stressed member 500 by contracting and unfolding the winding core 801. For example, when the flexible display panel 600 in the display device contracts, the stressed member 500 moves in the direction of the X2 axis, and the movement amount of the end portion of the tension belt 402 connected to the stressed member 500 is greater than that of the second planar display portion 603. At this time, the end portion of the tension belt 402 applies a force to the coil spring 800 through the stressed member 500, so that the winding core 801 in the coil spring 800 can be extended, and the force applied by the winding core 801 to the second planar display portion 603 can be ensured to be basically unchanged. Thus, it ensures that the flexible display panel 600 will not be subjected to an excessive pulling force to cause a bad phenomenon of functional layer failure. For example, the coil spring 800 in the display device may be a constant force coil spring.

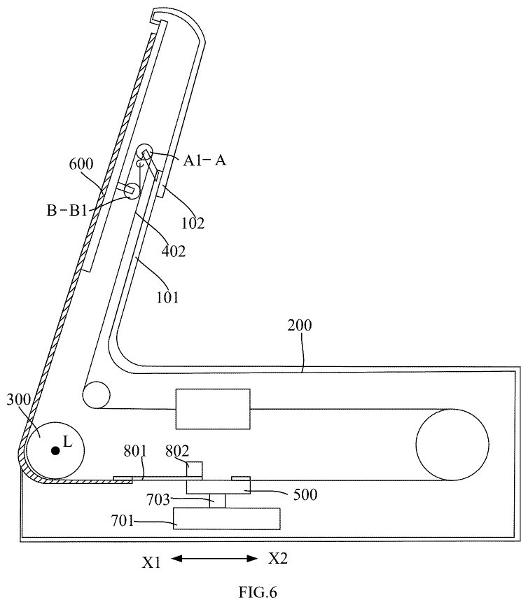

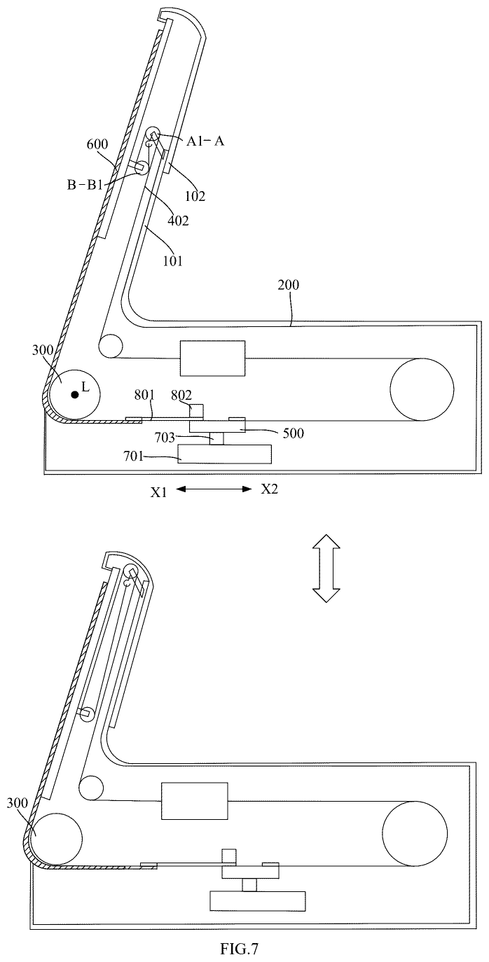

Optionally, please refer to FIG. 6 which is a sectional view of another display device provided by an embodiment of the present application. The pulley block 401 in the pulley assembly 400 may include at least one fixed pulley A and at least one movable pulley B. A bracket in the at least one movable pulley B may be fixedly connected to the sliding portion 102 in the first housing 100, and a bracket in the at least one fixed pulley A may be fixedly connected to the fixed portion 101 in the first housing 100. A central axis of a pulley in the at least one fixed pulley A and a central axis of a pulley in the at least one movable pulley B are both parallel to a central axis L of the roller 300, and the at least movable pulley B is closer to the roller 300 than the fixed pulley A. An end of the tension belt 402 in the pulley assembly 400 away from the stressed member 500 may be connected to the bracket in the movable block B or the bracket in the fixed block A, and the tension belt 402 may be wound around the pulley in at least one movable block B and the pulley in at least one fixed block A. In this case, by arranging at least one movable pulley B and at least one fixed pulley A in the pulley block 401, the end portion of the tension belt 402 away from the stressed member 500 can be connected to a bracket in the movable pulley B or the bracket in the fixed pulley A, and the end portion of the tension belt 402 away from the pulley block 401 can be connected to the stressed member 500, and the purpose of saving labor in the process of driving the flexible display panel 600 in the display device to unfold can be achieved through the cooperation of the tension belt 402 with the fixed pulley A and the movable pulley B in the pulley block 401. It should be noted that both the fixed pulley A and the movable pulley B in the pulley block 401 include a bracket and a pulley installed on the bracket, and the pulley can be rotatably connected to the bracket through a connecting shaft (not shown in the figure). The tension belt 402 in the pulley assembly 400 may be a belt-like structure made of a material such as rubber, plastic, or cloth, which is not specifically limited in the embodiment of the present application.

In the embodiment of the present application, the number of the fixed pulley A and the movable pulley B in the pulley block 401, the connection manner between the end of the tension belt 402 away from the stressed member 500 and the pulley, and the winding manner of the tension belt 402 on the pulleys in the pulley block 401 can be implemented in various optional manners. The follow embodiments of the present application are illustrated schematically by taking three optional implementations as examples.

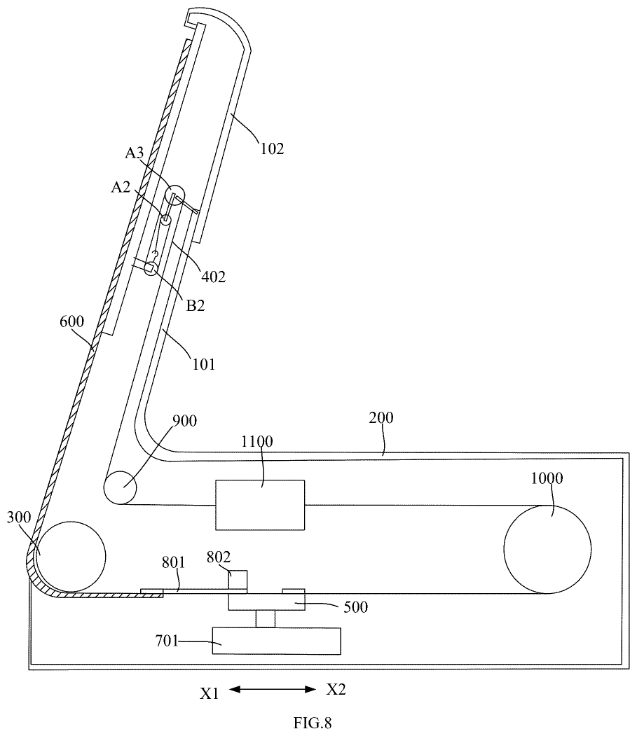

For the first optional implementation, please refer to FIGS. 6 and 7. FIG. 7 is a schematic view of an effect of switching between unfolding and contracting a flexible display panel in a display device provided by an embodiment of the present application. In a case that the pulley block 401 in the pulley assembly 400 may include one fixed block A1 and one movable block B1, an end of the tension belt 402 away from the stressed member 500 may be connected to the bracket in the fixed block A1, and the tension belt 402 may be successively wound around the pulley in the movable block B1 and the pulley in the fixed block A1 and is then connected to the stressed member 500. For example, in the actual assembly process, the bracket in the assembled movable pulley B1 may be firstly fixed on a back of the sliding portion 102 in the first housing 100 (i.e., a surface away from the first planar display portion), and then the bracket in the assembled fixed pulley A1 is fixed on the fixed portion 101 in the first housing 100; and then the end of the tension belt 402 away from the stressed member 500 is hung on the bracket in the fixed pulley A1. Finally, the tension belt 402 is successively wound around the pulley in the movable pulley B1 and the pulley in the fixed pulley A1, and then the other end of the tension belt 402 is fixed to the stressed member 500. In this way, the driving force required for driving the flexible display panel 600 to ascend can be reduced to half of the original driving force (i.e., the driving force directly applied to the movable plate in the related art) by the cooperation of the tension belt 402 with one fixed pulley A1 and one movable pulley B1.

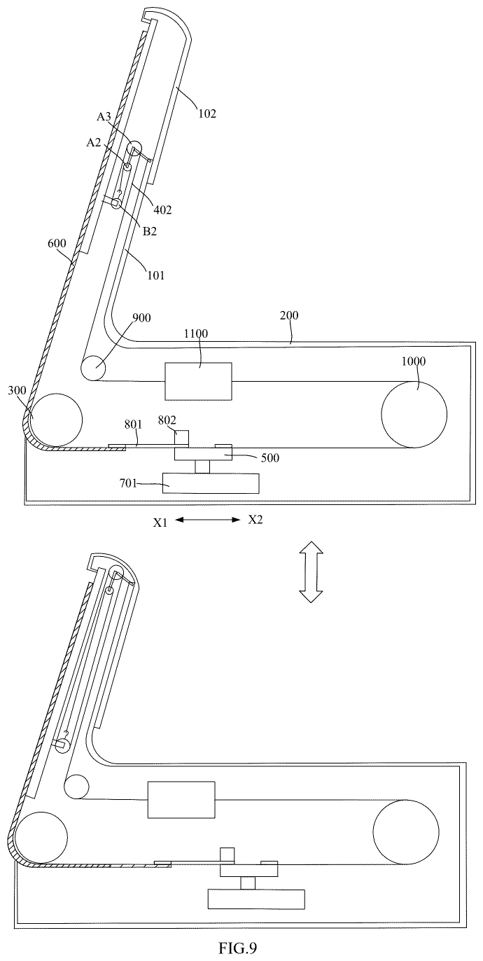

For the second optional implementation, please refer to FIGS. 8 and 9. FIG. 8 is a sectional view of yet another display device provided by an embodiment of the present application; and FIG. 9 is a schematic view of an effect of switching between unfolding and contracting the flexible display panel in the display device shown in FIG. 8. In a case that the pulley block 401 in the pulley assembly 400 may include two fixed pulleys and a movable pulley B2, the two fixed pulleys may be a first fixed pulley A2 and a second fixed pulley A3. The first fixed pulley A2 may be closer to the roller 300 than the second fixed pulley A3, and the end of the tension belt 402 away from the stressed member 500 may be connected to the bracket of the movable pulley B2, and the tension belt 402 may be successively wound around the pulley of the first fixed pulley A2, the pulley of the movable pulley B2 and the pulley of the second fixed pulley A3 and then be connected to the stressed member 500. For example, in the actual assembly process, the bracket in the assembled movable pulley B2 may be first fixed to the back of the sliding portion 102 in the first housing 100; and then the bracket in the assembled first fixed pulley A2 is fixed on the fixed portion 101 in the first housing 100 and the bracket in the assembled second fixed pulley A3 is fixed on the fixed portion 101 in the first housing 100. Then, the end of the tension belt 402 away from the stressed member 500 is hung on the bracket of the movable pulley B2. Finally the tension belt 402 is successively wound around the pulley of the first fixed pulley A2, the pulley of the movable pulley B2 and the pulley of the second fixed pulley A3, and then the other end of the tension belt 402 is fixed to the stressed member 500. In this way, the driving force required for driving the flexible display panel 600 to ascend can be reduced to one third of the original driving force (that is, the driving force directly applied to the movable plate in the related art) by the cooperation of the tension belt 402 with the two fixed pulleys and one movable pulley, that is, two thirds of the force can be saved.

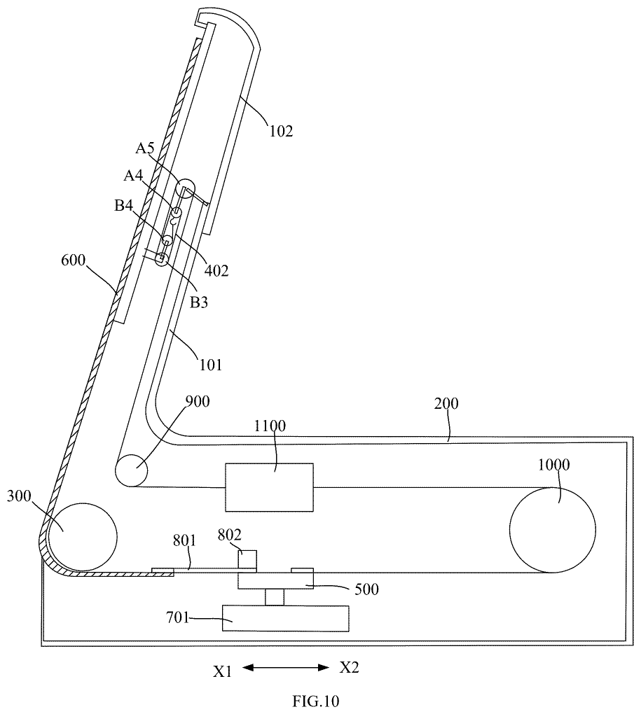

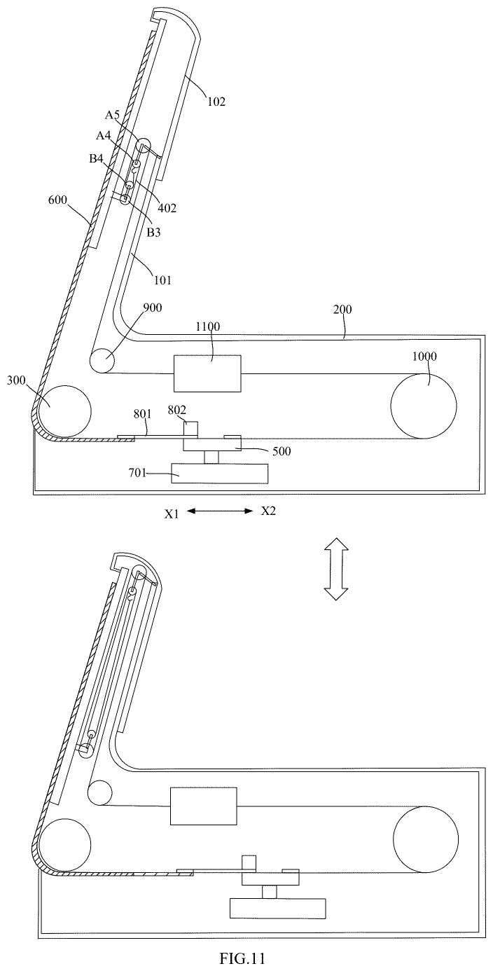

For the third optional implementation, please refer to FIGS. 10 and 11. FIG. 10 is a sectional view of a display device provided by another embodiment of the present application; and FIG. 11 is a schematic view of an effect of switching between unfolding and contracting the flexible display panel in the display device shown in FIG. 10. In a case that the pulley block 401 in the pulley assembly 400 may include two fixed pulleys and two movable pulleys, the two fixed pulleys may be a first fixed pulley A4 and a second fixed pulley A5, and the first fixed pulley A4 is closer to the roller 300 than the second fixed pulley A5. The two movable pulleys may be a first movable pulley B3 and a second movable pulley B4, and the first movable pulley B3 is closer to the roller 300 than the second movable pulley B4. The end of the tension belt 402 away from the stressed member 500 may be connected to the bracket of the first fixed pulley A4, and the tension belt 402 may be successively wound around the pulley of the second movable pulley B4, the pulley of the first fixed pulley A4, the pulley of the first movable pulley B3 and the pulley of the second fixed pulley A5 and then be connected to the stressed member 500. For example, in the actual assembly process, the bracket in the assembled first movable pulley B3 is fixed to the back of the sliding portion 102 in the first housing 100 and then the bracket in the assembled second movable pulley B4 is fixed to the back of the sliding portion 102 in the first housing 100, and then the bracket in the assembled first fixed pulley A4 is fixed on the fixed portion 101 in the first housing 100 and the bracket in the assembled second fixed pulley A5 is fixed on the fixed portion 101 in the first housing 100. Then, the end of the tension belt 402 away from the stressed member 500 is hung on the bracket of the first fixed pulley A4. Finally, the tension belt 402 is successively wound around the pulley of the second movable pulley B4, the pulley of the first fixed pulley A4, the pulley of the first movable pulley B3, and the pulley of the second fixed pulley A5 and then the other end of the tension belt 402 is fixed to the stressed member 500. In this way, the driving force required for driving the flexible display panel 600 to ascend can be reduced to one fourth of the original driving force (that is, the driving force directly applied to the movable plate in the related art) by the cooperation of the tension belt 402 with the two fixed pulleys and one movable pulley, that is, three fourths of the force can be saved.

Optionally, as shown in FIG. 6, FIG. 8 and FIG. 10, the arrangement direction of the at least one movable pulley B and the at least one fixed pulley A in the pulley block 401 may be parallel to a sliding direction of the sliding portion 102 relative to the fixed portion 101 in the first housing 100. In this case, the arrangement direction of the movable pulley B and the fixed pulley A in the pulley block 401 is parallel to the sliding direction of the sliding portion 102 in the first housing 100 relative to the fixed portion 101, so that the arrangement of the pulley block 401 in the first housing 100 is compact and a thickness of the first casing 100 in a direction perpendicular to the first planar display portion 602 in the flexible display panel 600 is small. It should be noted that, in other possible implementations, there may be a certain angle between the arrangement direction of the movable pulley and the fixed pulley in the pulley block and the sliding direction of the sliding portion relative to the fixed portion in the first housing.

In the embodiment of the present application, as shown in FIG. 9 and FIG. 11, the display device may further include a first steering shaft 900 and a second steering shaft 1000, and the first steering shaft 900 may be fixed at a position where the fixing portion 101 in the first housing 100 and the second housing 200 are connected. The second steering shaft 1000 may be located on a side of the stressed member 500 away from the roller 300 in the second housing 200, and the second steering shaft 1000 may be connected to the second housing 200. A central axis of the first steering shaft 900 and a central axis of the second steering shaft 1000 may be both parallel to a central axis of a roller 300. An end of the tension belt 402 in the pulley assembly 400 away from the pulley block 401 may successively wound around the first steering shaft 900 and the second steering shaft 1000 and then be connected to the stressed member 500. In this case, after being wound on the pulley block 401, the tension belt 402 can be also successively wound around the first steering shaft 900 and the second steering shaft 1000 and then be connected to the stressed member 500, so that the first steering shaft 900 and the second steering shaft 1000 can support the tension belt 402 and an entire length of the tension belt 402 in the direction perpendicular to the roller 300 is reduce and thus an entire length of the second housing 200 in the display device is small. For example, a cross-sectional shape of the first steering shaft 900 may be circular, and a cross-sectional shape of the second steering shaft 1000 may also be circular. A portion of the tension belt 402 located between the first steering shaft 900 and the second steering shaft 1000 is in parallel with a portion of the tension belt 402 located between the second steering shaft 1000 and the stressed member 500.

Optionally, please refer to FIGS. 10, 11 and 12. FIG. 12 is a sectional view of a display device provided by another embodiment of the present application. The tension belt 402 in the pulley assembly 400 may include a first sub-tension belt 4021 and a second sub-tension belt 4022. A first end of the first sub-tension belt 4021 may be connected to the pulley block 401, and a first end of the second sub-tension belt 4022 may be connected to the stressed member 500. The display device may further include a buffer assembly 1100 distributed between the first steering shaft 900 and the second steering shaft 1000, and two ends of the buffer assembly 1100 may be connected to a second end of the first sub-tension belt 4021 and a second end of the second sub-tension belt 4022, respectively. In this case, the buffer assembly 1100 is disposed between the second end of the first sub-tension belt 4021 and the second end of the second sub-tension belt 4022. In a case that the flexible display panel 600 descends at an excessive speed and results in an excessive instantaneous tension, the buffer assembly 1100 can absorb part of the energy to play a good buffering role, thereby ensuring that the flexible display panel 600 in the display device can be normally used all the time in the process of switching between the unfolded state and the contracted state.

In the embodiment of the present application, as shown in FIG. 12, the buffer assembly 1100 in the display device may include a first connecting member 1101 and a second connecting member 1102 clamped to each other, and an elastic element 1103 located between the first connecting member 1101 and the second connecting member 1102. Two ends of the elastic element 1103 can be respectively connected to the first connecting member 1101 and the second connecting member 1102. An end of the first connecting member 1101 away from the elastic element 1103 can be connected to the second end of the first sub-tension belt 4021. An end of the second connecting member 1102 away from the elastic element 1103 may be connected to the second end of the second sub-tension belt 4022. In this case, the first connecting member 1101 connected to the second end of the first sub-tension belt 4021, the second connecting member 1102 connected to the second end of the second tension belt 4022 and the elastic element 1103 respectively connected to the first connecting member 1101 and the second connecting member 1102 are arranged in the buffer assembly 1100. Thus, when the flexible display panel 600 operates normally, the first connecting member 1101 and the second connecting member 1102 are clamped. When the instantaneous tensile force of the tension belt 402 changes suddenly, the first connecting member 1101 and the second connecting member 1102 can be separated and the elastic element 1103 may be driven to be stretched to absorb kinetic energy. After the instantaneous tensile force is reduced, the elastic element 1103 can contract so that the first connecting member 1101 and the second connecting member 1102 are clamped. In the present application, at least one of the first connecting member 1101 and the second connecting member 1102 may be a structure made of an elastic material, and the second connecting member 1102 may have a cavity A1 for accommodating the elastic element 1103 and an opening A2 communicating with the cavity A1 and the first connecting member 1101 is clamped at the opening A2 of the second connecting member 1102. For example, the elastic element 1103 may be a helical spring.

Optionally, as shown in FIG. 12, one of the first connecting member 1101 and the second connecting member 1102 in the buffer assembly 1100 is provided with a clamping protrusion C1, and the other is provided with a clamping groove C2 matched with the clamping protrusion. After the clamping protrusion C1 is clamped to the clamping groove C2, the first connection member 1101 and the second connection member 1102 are clamped. In this case, the first connecting member 1101 and the second connecting member 1102 can be easily clamped or separated by the clamping protrusion C1 and the clamping groove C2. For example, the first connecting member 1101 may have a clamping protrusion C1, and the second connecting member 1102 may have a clamping groove C2, which is not specifically limited in the embodiment of the present application.

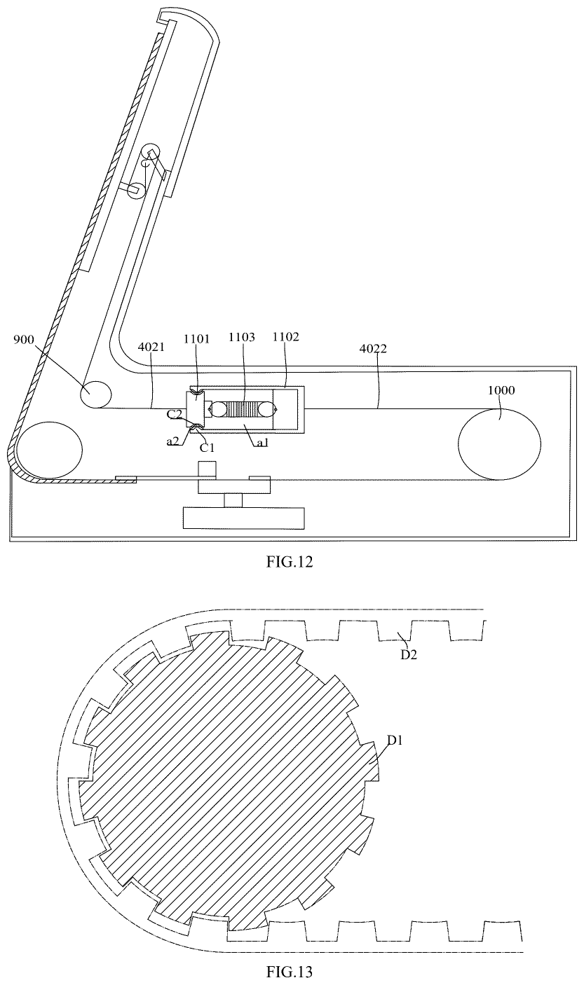

In the present application, please refer to FIG. 13 which is a schematic diagram of connection among a tension belt, a pulley and a steering shaft provided by an embodiment of the present application. The pulley in the pulley block 401, the first steering shaft 900 and the second steering shaft 1000 may all have external teeth D1, and the tension belt 402 may have internal teeth D2 that engage with the external teeth D1. In this case, the pulley, the first steering shaft 900, and the second steering shaft 1000 are engaged with the internal teeth D2 of the tension belt 402 through the external teeth D1, so that during the ascent or descent of the flexible display panel 600 in the display device, the tension belt 402 and the pulley, as well as the first steering shaft 900 and the second steering shaft 1000 do not slip or move therebetween.

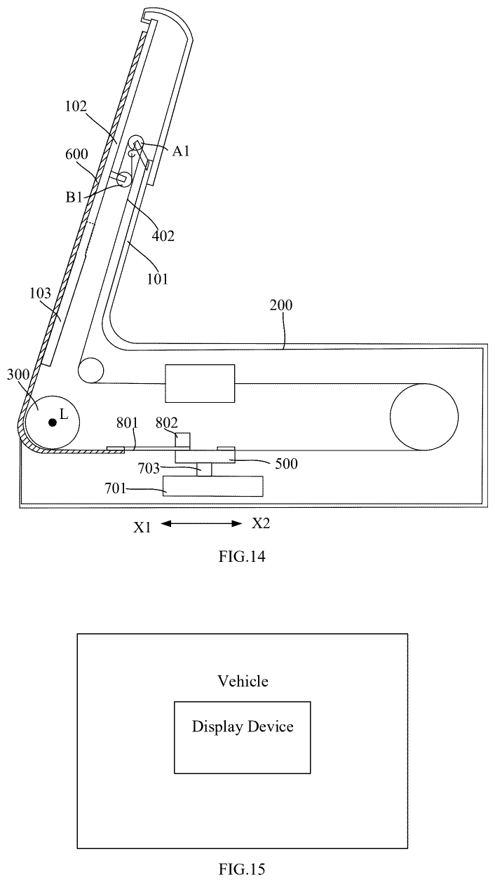

In the present application, the flexible display panel, the pulley block, the tension belt, the stressed member, and the like in the display device can form a closed system, so that when the display device is switched between the unfolded state and the contracted state, the flexible display panel is always in a tensioned and flattened state. However, in order to support the flexible display panel in the display device in a larger size after being unfolded, please refer to FIG. 14, which is a sectional view of another display device provided by another embodiment of the present application. The first housing 100 may further include an auxiliary fixing plate 103 that may be slidably connected to the sliding portion 102 and may be closer to the roller 300 than the sliding portion 102. For example, the sliding portion may have a plurality of first guide bars (not shown) arranged in parallel, the auxiliary fixing plate may have a plurality of second guide bars arranged in parallel, and the plurality of first guide bars and the plurality of second guide bars are staggered. In this way, the staggered first guide bars and the second guide bars can guide the sliding of the sliding portion 102 relative to the auxiliary fixing plate 103.

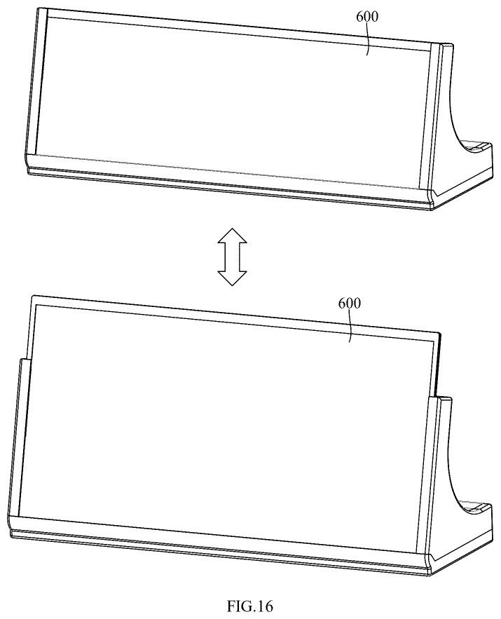

Embodiments of the present application also provide a vehicle, and please refer to FIG. 15 which is a block diagram of a vehicle provided by an embodiment of the present application. The vehicle may include a display device fixed in a cabin of the vehicle, which may be a display device given in any of the above. Exemplarily, the transportation vehicle may be a tool with a transport function such as a vehicle or a ship, and the display device may be fixed in a cockpit or a passenger compartment of the tool of transportation. For example, the display device may be fixed to a vehicle dashboard, a roof, or a seat in the driver's compartment of the vehicle.

Please refer to FIG. 16 which is a schematic view of an effect of switching between unfolding and contracting the display device in a vehicle provided by an embodiment of the present application. For example, when the display device is used on a vehicle (for example a car), the size of the flexible display panel extending from the display device can be flexibly adjusted, so that the flexible display panel is suitable for different use scenarios of the vehicle. In this way, it is possible to satisfy the user's requirements for entertainment and safety, and the requirement for the installation space of the vehicle is low. Especially for the large-size flexible display screen, the size of the flexible display screen can be adjusted according to different use scenarios in the vehicle environment. For example, when the vehicle is running, part of the flexible display screen is accommodated in the internal space of the display device, so that the display area of the flexible display screen is reduced, and the running information of the vehicle is provided by using a smaller display screen, thereby providing a good driving view. When the vehicle is in an entertainment state, a large part or all of the flexible display screen extends out of the internal space of the display device, so that the display area is increased, and the entertainment requirement of users is met.

It is noted that in the accompanying drawings, the dimensions of the layers and regions may be exaggerated for the sake of clarity of illustration. Moreover, it is understood that when an element or layer is referred to as being “on” another element or layer, it may be directly on the other element or there may be intervening layers. Also, it can be understood that when the element or layer is referred to as being “under” another element or layer, it can be directly under the other element, or more than one intermediate layer or element can exist. It is also understood that when a layer or element is referred to as being “between” two layers or elements, it may be the only layer between the two layers or elements, or there may be more than one intermediate layer or element. Similar reference marks throughout indicate similar elements.

In this application, the terms “first” and “second” are used for descriptive purposes only and are not to be understood as indicating or implying relative importance. The term “plurality” refers to two or more, unless otherwise expressly limited.

The foregoing are only optional embodiments of this application and are not intended to limit this application, and any modifications, equivalent substitutions, improvements, etc., made within the spirit and principles of this application shall be included in the scope of protection of this application.

1. A display device, comprising:
a first housing, wherein the first housing comprises a fixed portion and a sliding portion slidably connected to the fixed portion;
a second housing, wherein the second housing is fixedly connected to a side of the fixed portion away from the sliding portion, and an angle between the first housing and the second housing is less than 180 degrees;
a roller, wherein the roller is disposed between the first housing and the second housing, and the roller is rotatably connected to at least one of the first housing and the second housing;
a pulley assembly, wherein the pulley assembly comprises a pulley block in the first housing, and a tension belt wound around the pulley block, and the pulley block is respectively connected to the fixed portion and the sliding portion;
a stressed member, wherein the stressed member is disposed in the second housing and is fixedly connected to an end portion of the tension belt away from the pulley block; and
a flexible display panel, wherein the flexible display panel comprises a curled display portion wound on the roller and a first planar display portion and a second planar display portion disposed at two sides of the curled display portion, the first planar display portion is connected to the sliding portion in the first housing, and the second planar display portion is connected to the stressed member in the second housing.

2. The display device according to claim 1, wherein the pulley block comprises at least one fixed pulley and at least one movable pulley, a bracket in the at least one movable pulley is fixedly connected to the sliding portion, a bracket in the at least one fixed pulley is fixedly connected to the fixed portion, and the at least one movable pulley is closer to the roller than the at least one fixed pulley; and
wherein an end portion of the tension belt away from the stressed member is connected to a bracket in the movable pulley or a bracket in the fixed pulley, and the tension belt is wound around a pulley in the at least one movable pulley and a pulley in the at least one fixed pulley.

3. The display device according to claim 2, wherein in a case that the pulley block comprises one fixed pulley and one movable pulley, the end portion of the tension belt away from the stressed member is connected to the bracket in the fixed pulley, and the tension belt is successively wound around a pulley in the movable pulley and a pulley in the fixed pulley and is then connected to the stressed member.

4. The display device according to claim 2, wherein in a case that the pulley block comprises two fixed pulleys and one movable pulley, the two fixed pulleys are a first fixed pulley and a second fixed pulley, and the first fixed pulley is closer to the roller than the second fixed pulley; and
the end portion of the tension belt away from the stressed member is connected to a bracket in the movable pulley, and the tension belt is successively wound around a pulley of the first fixed pulley, a pulley of the movable pulley, and a pulley of the second fixed pulley and is then connected to the stressed member.

5. The display device according to claim 2, wherein in a case that the pulley block comprises two fixed pulleys and two movable pulleys, the two fixed pulleys are a first fixed pulley and a second fixed pulley, and the first fixed pulley is closer to the roller than the second fixed pulley;
the two movable pulleys are a first movable pulley and a second movable pulley, and the first movable pulley is closer to the roller than the second movable pulley; and
the end portion of the tension belt away from the stressed member is connected to a bracket in the first fixed pulley, and the tension belt is successively wound around a pulley of the second movable pulley, a pulley of the first fixed pulley, a pulley of the first movable pulley and a pulley of the second fixed pulley and is then connected to the stressed member.

6. The display device according to claim 2, wherein an arrangement direction of the at least one movable pulley and the at least one fixed pulley is parallel to a sliding direction of the sliding portion relative to the fixed portion.

7. The display device according to claim 1, wherein the display device also comprises a first steering shaft and a second steering shaft, the first steering shaft is fixed at a position where the fixed portion and the second housing are connected, and the second steering shaft is disposed at a side of the stressed member away from the roller in the second housing and is connected to the second housing; and a central axis of the first steering shaft and a central axis of the second steering shaft are both parallel to a central axis of the roller; and
wherein the end portion of the tension belt away from the pulley block is successively wound around the first steering shaft and the second steering shaft and is then connected to the stressed member.

8. The display device according to claim 7, wherein the tension belt comprises a first sub-tension belt and a second sub-tension belt, a first end of the first sub-tension belt is connected to the pulley block, and a first end of the second sub-tension belt is connected to the stressed member; and
the display device further comprises a buffer assembly arranged between the first steering shaft and the second steering shaft, and two ends of the buffer assembly are respectively connected to a second end of the first sub-tension belt and a second end of the second sub-tension belt.

9. The display device according to claim 8, wherein the buffer assembly comprises a first connecting member and a second connecting member which are clamped to each other and an elastic element disposed between the first connecting member and the second connecting member, two ends of the elastic element are respectively connected to the first connecting member and second connecting member; and
an end of the first connecting member away from the elastic element is connected to the second end of the first sub-tension belt, and an end of the second connecting member away from the elastic element is connected to the second end of the second sub-tension belt.

10. The display device according to claim 9, wherein
one of the first connecting member and the second connecting member is provided with a clamping protrusion and the other of the first connecting member and the second connecting member is provided with a clamping groove matched with the clamping protrusion; and
in a case that the clamping protrusion is clamped to the clamping groove, the first connection member and the second connection member are clamped.

11. The display device according to claim 7, wherein a pulley in the pulley block, the first steering shaft, and the second steering shaft are all provided with external teeth, and the tension belt is provided with internal teeth that engage with the external teeth.

12. The display device according to claim 1, wherein the display device further comprises a driving component fixed in the second housing and connected to the stressed member, and the driving component is configured to drive the stressed member to move along a direction perpendicular to the roller.

13. The display device according to claim 12, wherein the driving assembly comprises a driving motor, a transmission shaft and a transmission member, and the driving motor is fixed in the second housing and is connected to one end of the transmission shaft; the transmission member is sleeved on the transmission shaft and is connected to the stressed member; and the transmission shaft is arranged perpendicular to the roller; and
wherein the driving motor is configured to drive the transmission shaft to rotate such that the transmission member drives the stressed member to move along a length direction of the transmission shaft.

14. The display device according to claim 1, wherein the display device further comprises a coil spring disposed between the second planar display portion and the stressed member, the coil spring comprises a winding core and a fixed member fixed to one end of the winding core, the other end of the winding core is connected to the second planar display portion, and the fixed member is fixed to the stressed member.

15. A vehicle, comprising a display device fixed in a cabin of the vehicle, wherein the display device is the display device as defined in claim 1.

16. The display device according to claim 3, wherein an arrangement direction of the at least one movable pulley and the at least one fixed pulley is parallel to a sliding direction of the sliding portion relative to the fixed portion.

17. The display device according to claim 2, wherein the display device also comprises a first steering shaft and a second steering shaft, the first steering shaft is fixed at a position where the fixed portion and the second housing are connected, and the second steering shaft is disposed at a side of the stressed member away from the roller in the second housing and is connected to the second housing; and a central axis of the first steering shaft and a central axis of the second steering shaft are both parallel to a central axis of the roller; and
wherein the end portion of the tension belt away from the pulley block is successively wound around the first steering shaft and the second steering shaft and is then connected to the stressed member.

18. The display device according to claim 2, wherein the display device further comprises a driving component fixed in the second housing and connected to the stressed member, and the driving component is configured to drive the stressed member to move along a direction perpendicular to the roller.

19. The display device according to claim 2, wherein the display device further comprises a coil spring disposed between the second planar display portion and the stressed member, the coil spring comprises a winding core and a fixed member fixed to one end of the winding core, the other end of the winding core is connected to the second planar display portion, and the fixed member is fixed to the stressed member.

20. The display device according to claim 3, wherein the display device further comprises a coil spring disposed between the second planar display portion and the stressed member, the coil spring comprises a winding core and a fixed member fixed to one end of the winding core, the other end of the winding core is connected to the second planar display portion, and the fixed member is fixed to the stressed member.
